(19) United States
(12) Patent Application Publication
(10) Pub. No.: US 2023/0253275 A1
(43) Pub. Date: Aug. 10, 2023

(54) SEMICONDUCTOR DEVICE AND SEMICONDUCTOR DEVICE MANUFACTURING METHOD

(71) Applicant: FUJI ELECTRIC CO., LTD., KAWASAKI-SHI (JP)

(72) Inventor: Nobuhiro HIGASHI, Matsumoto-city (JP)

(73) Assignee: FUJI ELECTRIC CO., LTD., KAWASAKI-SHI (JP)

(21) Appl. No.: 18/089,851

(22) Filed: Dec. 28, 2022

(30) Foreign Application Priority Data
Feb. 4, 2022 (JP) 2022-016196

(51) Int. Cl. H01L 23/053; H01L 23/31; H01L 23/08; H01L 21/52; H01L 21/56; H01L 23/00

(52) U.S. Cl. CPC H01L 23/053; H01L 23/3121; H01L 23/08; H01L 21/52; H01L 21/56; H01L 23/562; H01L 2224/48137; H01L 2224/48175; H01L 24/48

(57) ABSTRACT

A semiconductor device, including a semiconductor chip, a case having an opening formed therein and an inner wall communicating with the opening, and a sealing member. The inner wall surrounds a housing space for accommodating the semiconductor chip. The sealing member fills the housing space to seal the semiconductor chip. The sealing member has a side surface and a sealing surface. The side surface has a contact area contacting the inner wall of the case. The contact area is positioned, in a depth direction of the semiconductor device, closer to the semiconductor chip than is the sealing surface of the sealing member.

### CROSS-REFERENCE TO RELATED APPLICATION

This application is based upon and claims the benefit of priority of the prior Japanese Patent Application No. 2022-016196, filed on Feb. 4, 2022, the entire contents of which are incorporated herein by reference.

### BACKGROUND OF THE INVENTION

### 1. Field of the Invention

The embodiments discussed herein relate to a semiconductor device and a semiconductor device manufacturing method.

### 2. Background of the Related Art

Semiconductor devices include power devices and are used as power conversion devices. The power devices include semiconductor chips. The semiconductor chips are insulated gate bipolar transistors (IGBTs) and power metal oxide semiconductor field effect transistors (MOSFETs), for example. In such a semiconductor device, semiconductor chips are accommodated in a case and the inside of the case is sealed with a sealing member.

See, for example, Japanese Laid-open Patent Publication No. 2017-17109.

Different materials are used for the case and the sealing member in the above semiconductor device. Therefore, the case and sealing member have different linear expansion coefficients. When the semiconductor device is subjected to temperature changes, internal stress is generated accordingly. Such stress may be concentrated in the sealing member of the semiconductor device, which may cause a crack. Such a crack reduces the power cycle resistance of the semiconductor device and in turn reduces the reliability of the semiconductor device against the temperature changes.

### SUMMARY OF THE INVENTION

According to one aspect, there is provided a semiconductor device, including: a semiconductor chip; a case having an opening formed therein, and an inner wall communicating with the opening, the inner wall surrounding a housing space for accommodating the semiconductor chip; and a sealing member filling the housing space to seal the semiconductor chip, the sealing member having a side surface and a sealing surface, the side surface having a contact area contacting the inner wall of the case, wherein the contact area is positioned, in a depth direction of the semiconductor device, closer to the semiconductor chip than is the sealing surface of the sealing member.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a side sectional view of a semiconductor device according to a first embodiment;

FIG. 2 is a plan view of a main part (except for a sealing member) of the semiconductor device according to the first embodiment;

FIG. 3 is a plan view of the main part of the semiconductor device according to the first embodiment;

FIG. 4 is a side sectional view of a main part of the semiconductor device according to the first embodiment;

FIG. 5 is a side sectional view of a semiconductor device according to a reference example;

FIG. 6 is a flowchart illustrating a semiconductor device manufacturing method according to the first embodiment;

FIG. 7 is a side sectional view for describing a housing step included in the semiconductor device manufacturing method according to the first embodiment;

FIG. 8 is a side sectional view for describing a sealing injection step included in the semiconductor device manufacturing method according to the first embodiment;

FIG. 9 is a side sectional view for describing a jig attachment step included in the semiconductor device manufacturing method according to the first embodiment;

FIG. 10 illustrates a jig used in the semiconductor device manufacturing method according to the first embodiment;

FIG. 11 is a side sectional view for describing the jig attachment step included in the semiconductor device manufacturing method according to the first embodiment;

FIG. 12 is a side sectional view of a main part of a semiconductor device according to a modification 1-1 of the first embodiment;

FIG. 13 is a side sectional view of the main part for describing a jig attachment step included in a semiconductor device manufacturing method according to the modification 1-1 of the first embodiment;

FIG. 14 is a flowchart illustrating a semiconductor device manufacturing method according to a second embodiment;

FIG. 15 is a side sectional view for describing a jig attachment step included in the semiconductor device manufacturing method according to the second embodiment; and

FIG. 16 is a plan view of a main part for describing the jig attachment step included in the semiconductor device manufacturing method according to the second embodiment.

### DETAILED DESCRIPTION OF THE INVENTION

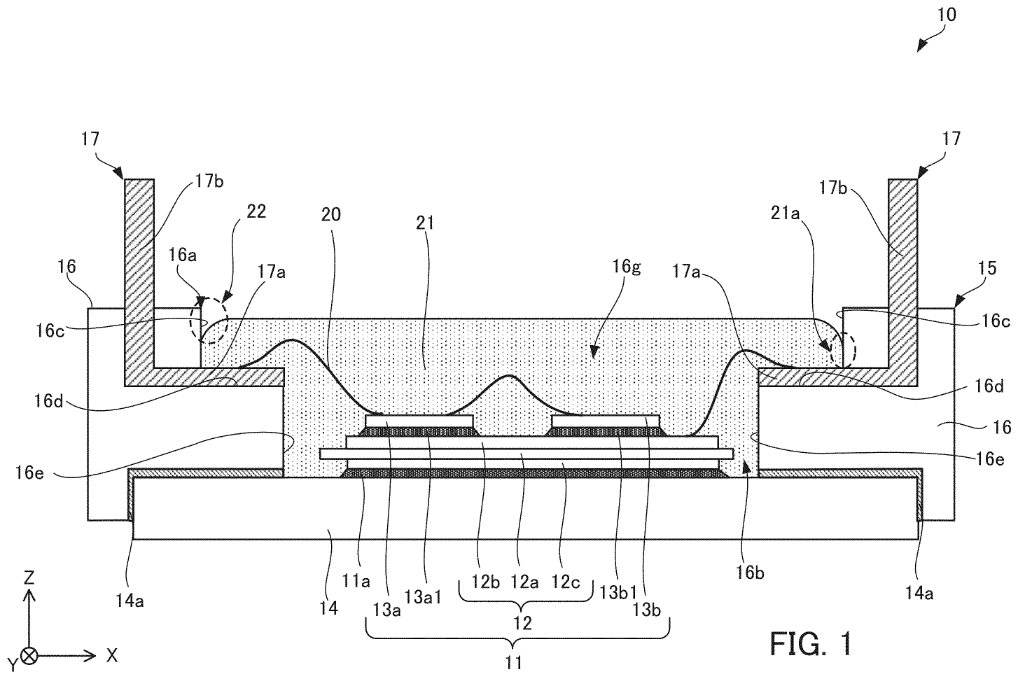

Hereinafter, some embodiments will be described with reference to the accompanying drawings. In the following description, the terms “front surface” and “top surface” refer to surfaces facing the +Z direction in a semiconductor device 10 of FIG. 1. Similarly, the term “up” refers to the +Z direction in the semiconductor device 10 of FIG. 1. The terms “rear surface” and “bottom surface” refer to surfaces facing the −Z direction in the semiconductor device 10 of FIG. 1. Similarly, the term “down” refers to the −Z direction in the semiconductor device 10 of FIG. 1. The term “side surface” refers to a surface connecting a “front surface” or “top surface” and a “rear surface” or “bottom surface” in the semiconductor device 10 of FIG. 1. For example, a “side surface” is a surface facing one of the ±X directions and ±Y directions in the semiconductor device 10 of FIG. 1. The same directionality applies to all drawings. The terms “front surface,” “top surface,” “up,” “rear surface,” “bottom surface,” “down,” and “side surface” are used for convenience to describe relative positional relationships, and do not limit the technical ideas of the embodiments. For example, the terms “up” and “down” are not always related to the vertical directions to the ground. That is, the “up” and “down” directions are not limited to the gravity direction. In addition, in the following description, the term “main component” refers to a component contained at a volume ratio of 80 vol % or more. Expressions “being substantially parallel” and “being substantially horizontal” mean that the angle formed by two objects falls within the range of 170° to 190°, inclusive. Expressions “being substantially perpendicular” and “being substantially vertical” mean that the angle formed by two objects falls within the range of 85° to 95°, inclusive.

### First Embodiment

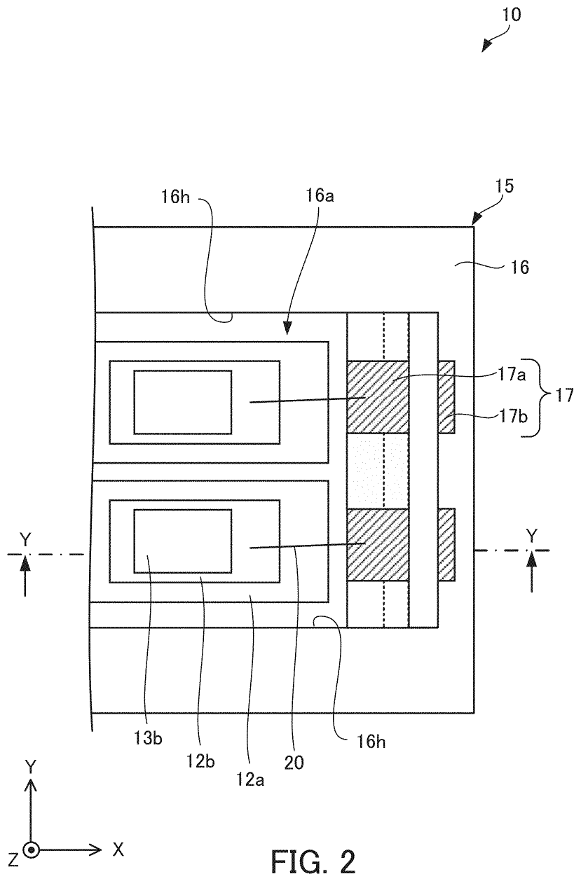

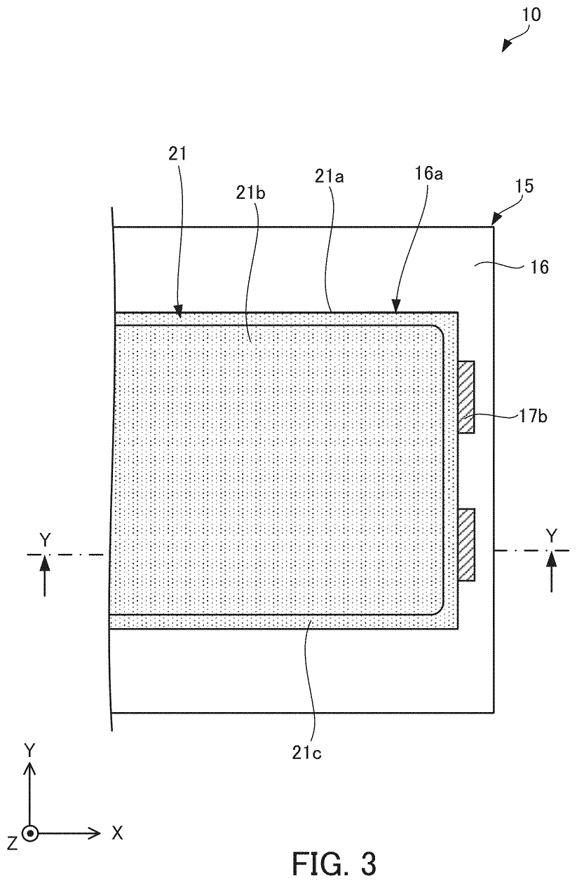

A semiconductor device according to a first embodiment will be described with reference to FIGS. 1 to 3. FIG. 1 is a side sectional view of a semiconductor device according to the first embodiment. FIG. 2 is a plan view of a main part (except for a sealing member) of the semiconductor device according to the first embodiment, and FIG. 3 is a plan view of the main part of the semiconductor device according to the first embodiment. In this connection, FIG. 1 is a sectional view taken along the dash-dotted line Y-Y of FIGS. 2 and 3. The illustration of a sealing member 21 is omitted in FIG. 2. FIGS. 2 and 3 are plan views around an external connection terminal 17 of FIG. 1.

As illustrated in FIGS. 1 and 2, the semiconductor device 10 includes a heat dissipation plate 14 that is rectangular in plan view, a semiconductor unit 11 disposed on the front surface of the heat dissipation plate 14, a case 15 that is provided on the outer periphery of the heat dissipation plate 14 and accommodates the semiconductor unit 11 therein, and a sealing member 21 sealing the inside of the case 15. The semiconductor unit 11 includes an insulated circuit substrate 12, and semiconductor chips 13a and 13b disposed on the front surface of the insulated circuit substrate 12 via bonding materials 13a1 and 13b1.

The insulated circuit substrate 12 includes an insulating plate 12a, a plurality of circuit patterns 12b provided on the front surface of the insulating plate 12a, and a metal plate 12c provided on the rear surface of the insulating plate 12a. The insulating plate 12a and metal plate 12c are rectangular in plan view. In addition, the corners of the insulating plate 12a and metal plate 12c may be rounded or chamfered. The metal plate 12c is smaller in size than the insulating plate 12a in plan view and is positioned inside the insulating plate 12a.

For example, as the insulating plate 12a, an organic insulating layer, an insulating resin, or a ceramic substrate may be used. The organic insulating layer is made of a combination of a resin with low thermal resistance and a material with high thermal conductivity. Examples of the former resin include an epoxy resin and a liquid crystal polymer insulating resin. Examples of the latter material include boron nitride, aluminum oxide, and silicon oxide. Examples of the insulating resin include a paper phenolic board, a paper epoxy board, a glass composite board, and a glass epoxy board. The ceramic substrate is made of ceramics with high thermal conductivity. For example, the ceramics are made from materials including aluminum oxide, aluminum nitride, or silicon nitride as a main component. In addition, the insulating plate 12a is rectangular in plan view. The thickness of the insulating plate 12a is in the range of 0.2 mm to 2.5 mm, inclusive.

The plurality of circuit patterns 12b are formed on the entire front surface of the insulating plate 12a except the edge portion thereof. Preferably, in plan view, edges of the plurality of circuit patterns 12b facing the outer periphery of the insulating plate 12a are aligned with the corresponding edges of the metal plate 12c facing the outer periphery of the insulating plate 12a. With this configuration, the insulated circuit substrate 12 maintains the stress balance between the circuit patterns 12b and the metal plate 12c on the rear surface of the insulating plate 12a. Therefore, damage, such as an excess warpage and a crack, to the insulating plate 12a is prevented. The circuit patterns 12b are made of a material with high electrical conductivity. Examples of the material include copper, aluminum, and an alloy containing at least one of these. The thicknesses of the circuit patterns 12b are in the range of 0.1 mm to 2.0 mm, inclusive, and more preferably in the range of 0.2 mm to 1.0 mm, inclusive. In addition, plating may be performed on the circuit patterns 12b using a high corrosion resistance material. Examples of such a material include nickel, a nickel-phosphorus alloy, and a nickel-boron alloy. The thickness of the plating film is preferably 1 μm or more and is more preferably 5 μm or more. The circuit patterns 12b are formed on the insulating plate 12a by forming a metal plate on the front surface of the insulating plate 12a and performing etching or another on the metal plate. Alternatively, the circuit patterns 12b cut out of a metal plate in advance may be press-bonded to the front surface of the insulating plate 12a. In this connection, the circuit patterns 12b are just an example, and the quantity, shapes, sizes, and others of the circuit patterns may be determined as appropriate.

The metal plate 12c is made of a metal with high thermal conductivity. Examples of the material include copper, aluminum, and an alloy containing at least one of these. The thickness of the metal plate 12c is preferably in the range of 0.1 mm and 2.0 mm, inclusive, and more preferably in the range of 0.2 mm to 1.0 mm, inclusive. Plating may be performed on the surface of the metal plate 12c to improve its corrosion resistance. Examples of the plating material used here include nickel, a nickel-phosphorus alloy, and a nickel-boron alloy. The thickness of the plating film is preferably 1 μm or more and is more preferably 5 μm or more.

As the insulated circuit substrate 12 configured as above, a direct copper bonding (DCB) substrate or an active metal brazed (AMB) substrate may be used, for example. The insulated circuit substrate 12 transfers heat generated by the semiconductor chips 13a and 13b (to be described below), through the circuit patterns 12b, the insulating plate 12a, and the metal plate 12c to the rear surface of the insulated circuit substrate 12, thereby dissipating the heat.

The semiconductor chips 13a and 13b are power devices that are made of silicon, silicon carbide, or gallium nitride. The semiconductor chip 13a includes a switching element. The switching element is a power MOSFET or an IGBT, for example. The semiconductor chip 13a of this type has an input electrode (a drain electrode in a power MOSFET, and a collector electrode in an IGBT) serving as a main electrode on the rear surface thereof and has a gate electrode serving as a control electrode and an output electrode (a source electrode in the power MOSFET, and an emitter electrode in the IGBT) serving as a main electrode on the front surface thereof.

The semiconductor chip 13b includes a diode element. The diode element is a free wheeling diode (FWD) such as a Schottky barrier diode (SBD) or a P-intrinsic-N (PiN) diode. The semiconductor chip 13b of this type has an output electrode (a cathode electrode) serving as a main electrode on the rear surface thereof and has an input electrode (an anode electrode) serving as a main electrode on the front surface thereof.

The rear surfaces of the semiconductor chips 13a and 13b are bonded to the circuit patterns 12b using the bonding materials 13a1 and 13b1. The bonding materials 13a1 and 13b1 are solder or a sintered material. The solder is a lead-free solder containing a predetermined alloy as a main component. For example, the predetermined alloy is at least one of a tin-silver-copper alloy, a tin-zinc-bismuth alloy, a tin-copper alloy, a tin-silver-indium-bismuth alloy, and a tin-antimony alloy. In addition, the solder may contain an additive. Examples of the additive include nickel, germanium, cobalt, and silicon. In addition, examples of the sintered material used for the sintering bonding include powders of silver, iron, copper, aluminum, titanium, nickel, tungsten and molybdenum. The thicknesses of the semiconductor chips 13a and 13b are in the range of 80 μm to 500 μm, inclusive, for example, and are approximately 200 μm on average. In place of the semiconductor chips 13a and 13b, a semiconductor chip including a reverse-conducting (RC)-IGBT switching element, which integrates an IGBT and FWD into one chip, may be disposed. In this connection, FIG. 1 illustrates a set of semiconductor chips 13a and 13b disposed on the insulated circuit substrate 12, by way of example. Not only one set but also plural sets of semiconductor chips may be disposed where appropriate according to design.

The heat dissipation plate 14 has a flat plate shape and is rectangular in plan view. The heat dissipation plate 14 is made of a metal with high thermal conductivity. Examples of this material include aluminum, iron, silver, copper, and an alloy containing at least one of these. Examples of such an alloy may be metal composite materials such as aluminum-silicon carbide (Al-SiC) and magnesium-silicon carbide (Mg-SiC). Plating may be performed on the surface of the heat dissipation plate 14 to improve its corrosion resistance. Examples of the plating material used here include nickel, a nickel-phosphorus alloy, and a nickel-boron alloy. A cooling unit (not illustrates) may be attached to the rear surface of the case 15 including the heat dissipation plate 14 via a thermal conductive material. The thermal conductive material is a thermal interface material (TIM). For example, TIM includes generic terms for various materials including thermal conductive grease, elastomer sheet, room temperature vulcanization (RTV) rubber, gel, phase change material, solder, and silver solder. This improves the heat dissipation property of the semiconductor device 10. The cooling unit in this case is made of a metal with high thermal conductivity. Examples of the metal include aluminum, iron, silver, copper, and an alloy containing at least one of these. In this connection, the heat dissipation plate 14 does not need to have a flat plate shape. For example, the heat dissipation plate 14 may have a rough rear surface (a principal surface opposite to a surface on which the semiconductor unit 11 is displaced). In addition, the cooling unit is a heat sink with one or more fins or a cooling device using cool water, for example. In addition, the heat dissipation plate 14 may be integrally formed with such a cooling unit.

The case 15 has a frame portion 16 and external connection terminals 17 attached to the frame portion 16. The frame portion 16 is rectangular in plan view and has a frame shape surrounding a housing space 16g. The housing space 16g is an opening extending from a top opening 16a at the front surface of the case 15 to a bottom opening 16b at the rear surface thereof. The top opening 16a may be larger in size than the bottom opening 16b. In this connection, an opening communicating with the bottom opening 16b is formed in the rear surface of the frame portion 16 to allow the heat dissipation plate 14 to enter.

In addition, an upper inner wall 16c surrounds the upper portion of the housing space 16g and forms the top opening 16a communicating with the housing space 16g. A lower inner wall 16e surrounds the lower portion of the housing space 16g and forms the bottom opening 16b communicating with the housing space 16g. The frame portion 16 has a step 16d between the upper inner wall 16c and the lower inner wall 16e on each short side thereof in plan view. The upper inner wall 16c is formed substantially perpendicular to the front surface of the frame portion 16. The step 16d is formed substantially perpendicular to the upper inner wall 16c. The lower inner wall 16e is formed substantially perpendicular to the step 16d. As described above, on each short side of the frame portion 16 in plan view, the lower inner wall 16e is positioned closer to the center of the housing space 16g than the upper inner wall 16c, by a distance corresponding to the step 16d.

In addition, on each long side of the frame portion 16 in plan view, an inner wall 16h extends substantially vertically downward from the front surface of the frame portion 16. Thus, the top opening 16a and the bottom opening 16b are enclosed by the upper inner walls 16c and lower inner walls 16e on the short sides of the frame portion 16 and the inner walls 16h on the long sides thereof. In this connection, the semiconductor device 10 may be designed such that the steps 16d are not formed but the upper inner wall 16c on each short side is formed straight so as to extend substantially vertically downward from the front surface of the frame portion 16 toward the rear surface thereof.

The above frame portion 16 is formed by injection molding using a thermoplastic resin containing a filler. This material has an elastic modulus of 3 Gpa to 25 Gpa, inclusive, and has a linear expansion coefficient of 7×10⁻⁶/K to 100×10⁻⁶/K, inclusive. Examples of the resin include a polyphenylene sulfide (PPS) resin, a polybutylene terephthalate (PBT) resin, and a polyamide (PA) resin. Examples of the filler include a glass fiber, glass beads, calcium carbide, talc, magnesium oxide, and aluminum hydroxide. Especially, for the frame portion 16, a PPS resin containing any of the fillers is used.

The external connection terminals 17 have a flat plate shape, and have an L shape in side view. The external connection terminals 17 are integrally formed with the frame portion 16. Each external connection terminal 17 includes an inner wire portion 17a and an outer wire portion 17b provided substantially perpendicular to the inner wire portion 17a. The inner wire portion 17a is positioned in parallel to the front surface of the frame portion 16 in the frame portion 16. One end of the inner wire portion 17a extends substantially perpendicularly from the upper inner wall 16c toward the housing space 16g, with the front surface of the one end exposed on the step 16d. The outer wire portion 17b is positioned in substantially parallel to the upper inner wall 16c of the frame portion 16 in the frame portion 16. One end of the outer wire portion 17b integrally connects to the other end of the inner wire portion 17a inside the frame portion 16. The other end of the outer wire portion 17b extends substantially perpendicularly to the front surface of the frame portion 16.

The external connection terminals 17 are made of a material with high electrical conductivity. Examples of this material include copper, aluminum, and an alloy containing at least one of these. The external connection terminals 17 have uniform thickness throughout. plating may be performed on the external connection terminals 17 using a high corrosion resistance material. Examples of the plating material include aluminum, nickel, titanium, chromium, molybdenum, tantalum, niobium, tungsten, vanadium, bismuth, zirconium, hafnium, gold, silver, platinum, palladium, and an alloy containing at least one of these.

The outer periphery of the front surface of the heat dissipation plate 14 having the semiconductor unit 11 bonded thereto is bonded via an adhesive 14a to the rear surface of the frame portion 16 of the case 15 on the side thereof closer to the bottom opening 16b. Thereby, the semiconductor unit 11 is positioned in the housing space 16g of the frame portion 16. In this connection, a lid (not illustrated) may be bonded via an adhesive to the front surface of the frame portion 16 on the side closer to the top opening 16a, although it is not illustrated. In addition, for the adhesive 14a, for example, a thermosetting resin adhesive or an organic adhesive is used. For example, the thermosetting resin adhesive contains an epoxy resin or phenolic resin as a main component. For example, the organic adhesive is an elastomer adhesive containing a silicone rubber or chloroprene rubber as a main component.

Inside the case 15, bonding areas set on the inner wire portions 17a of the external connection terminals 17 and the circuit patterns 12b and semiconductor chips 13a and 13b of the insulated circuit substrate 12 are electrically connected with wiring members. Examples of the wiring members include bonding wires 20 illustrated in FIG. 1. The bonding wires 20 are made of a material with high electrical conductivity. Examples of the material include gold, silver, copper, aluminum, and an alloy containing at least one of these. In addition, the diameters of the bonding wires 20 are in the range of 110 μm to 500 μm, inclusive. In this connection, the wiring members are not limited to the bonding wires 20, but a lead frame may be used.

Then, the sealing member 21 is injected in the housing space 16g of the frame portion 16 to seal the semiconductor unit 11. After the sealing member 21 is injected, a space 22 (enclosed by a broken circle at the upper edge of the sealing member 21 in FIG. 1) is formed in a loop shape along the entire periphery of the top opening 16a at the side of the upper inner wall 16c where the top opening 16a is positioned. The sealing member 21 will be described in detail below.

The sealing member 21 is a thermosetting resin mixed with a filler. Such a material has an elastic modulus of 3 Gpa to 25 Gpa, inclusive, and has a linear expansion coefficient of 7×10⁻⁶/K to 30×10⁻⁶/K, inclusive. Examples of the thermosetting resin include an epoxy resin, phenolic resin, maleimide resin, and polyester resin. The filler is ceramics that are insulative and have high thermal conductivity. Examples of the filler include silicon oxide, aluminum oxide, boron nitride, and aluminum nitride. The content of the filler in the whole sealing member 21 is in the range of 10 vol % to 70 vol %, inclusive.

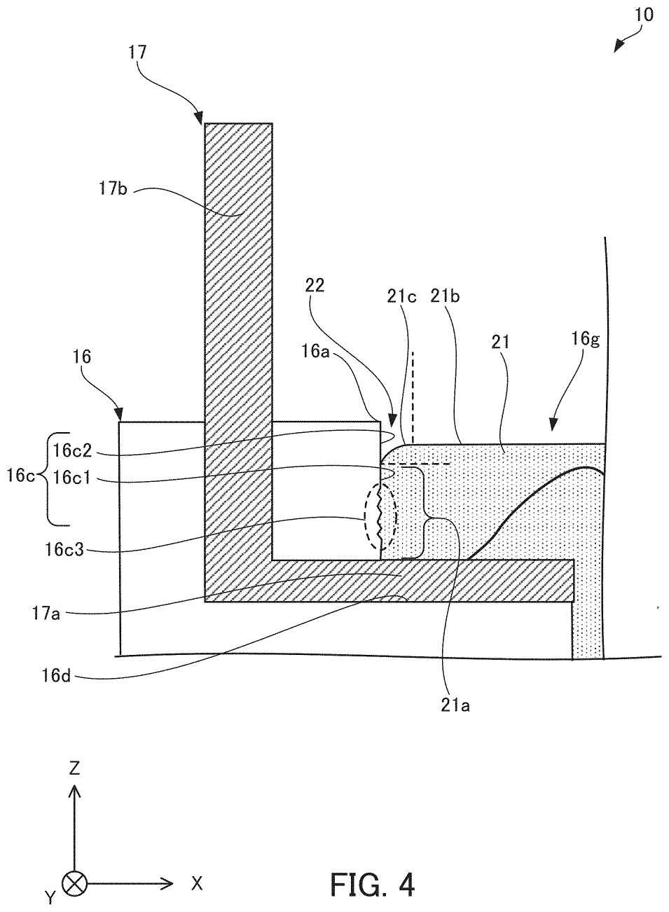

The following will describe the sealing member 21 for the frame portion 16 with reference to FIG. 4. FIG. 4 is a side sectional view of a main part of the semiconductor device according to the first embodiment. In this connection, FIG. 4 illustrates a part of the frame portion 16 of FIG. 1 around a step 16d.

As described earlier, the sealing member 21 is injected in the housing space 16g of the frame portion 16 to seal the semiconductor unit 11. The sealing member 21 has a contact area 21a, a sealing surface 21b, and a sealing connecting surface 21c. The contact area 21a (an area enclosed by a broken circle in FIG. 1 where the sealing member 21 and the upper inner wall 16c contact each other) is part of the side surface of the sealing member 21 and contacts the upper inner wall 16c. This contact area 21a is continuous along the entire periphery of the side surface of the sealing member 21. The sealing surface 21b is the top surface of the sealing member 21. In plan view, the area of the sealing surface 21b is smaller in size than the open area of the top opening 16a, and the sealing surface 21b is positioned inside the top opening 16a. In the sealing member 21, the outer edge of the contact area 21a at the side thereof where the top opening 16a is positioned is closer to the semiconductor chips 13a and 13b accommodated in the housing space 16g than the sealing surface 21b. In other words, the sealing surface 21b is positioned above (in the +z direction) the contact area 21a and below the top opening 16a (in the −z direction).

The sealing connecting surface 21c connects the outer edge of the sealing surface 21b and the outer edge at the upper end of the contact area 21a at the side thereof where the top opening 16a is positioned, over the entire periphery. In addition, the sealing connecting surface 21c rises from the contact area 21a such that the sealing connecting surface 21c and an attachment area 16c2 (to be described later) of the upper inner wall 16c form an acute angle in side view. This sealing connecting surface 21c is formed in a chamfered shape over the entire periphery between the contact area 21a and the sealing surface 21b. For example, the chamfered shape is as if the entire peripheral edge of the sealing member 21 at the side thereof where the top opening 16a is positioned is chamfered. Referring to FIG. 4, as if the entire peripheral edge is chamfered in an R-shape, the sealing connecting surface 21c rises from the contact area 21a, has an R shape with a curvature, and connects to the outer edge of the sealing surface 21b.

In addition, the upper inner wall 16c of the frame portion 16 has a contacted area 16c1 and the attachment area 16c2. The contacted area 16c1 is part of the upper inner wall 16c contacted by the contact area 21a of the sealing member 21 injected in the housing space 16g of the frame portion 16, and the contacted area 16c1 extends down to the step 16d as its bottom. The contacted area 16c1 may have a roughened area 16c3 subjected to a roughening treatment. The attachment area 16c2 may be the whole area of the upper inner wall 16c above the contacted area 16c1 (in the +z direction). That is, the attachment area 16c2 is an area between the contacted area 16c1 and the top opening 16a. The attachment area 16c2 may be adjacent to the contacted area 16c1. The attachment area 16c2 of the upper inner wall 16c and the sealing connecting surface 21c of the sealing member 21 have the space 22 formed therebetween. In this connection, in the present embodiment, the external connection terminals 17 are formed on the steps 16d. In the case where the external connection terminals 17 are not formed on the steps 16d, the sealing member 21 covers the steps 16d of the frame portion 16. In this case, the bottom of the sealing member 21 contacting the contacted area 16c1 of the frame portion 16 contacts the step 16d.

In addition, as in the upper inner wall 16c, each inner wall 16h of the frame portion 16 on the long sides has the contacted area 16c1 and the attachment area 16c2. The contacted area 16c1 of the inner wall 16h extends down to the bottom opening 16b as its bottom. Therefore, the space 22 is continuously provided along the entire periphery of the top opening 16a between the attachment area 16c2 and the sealing connecting surface 21c (see FIG. 4).

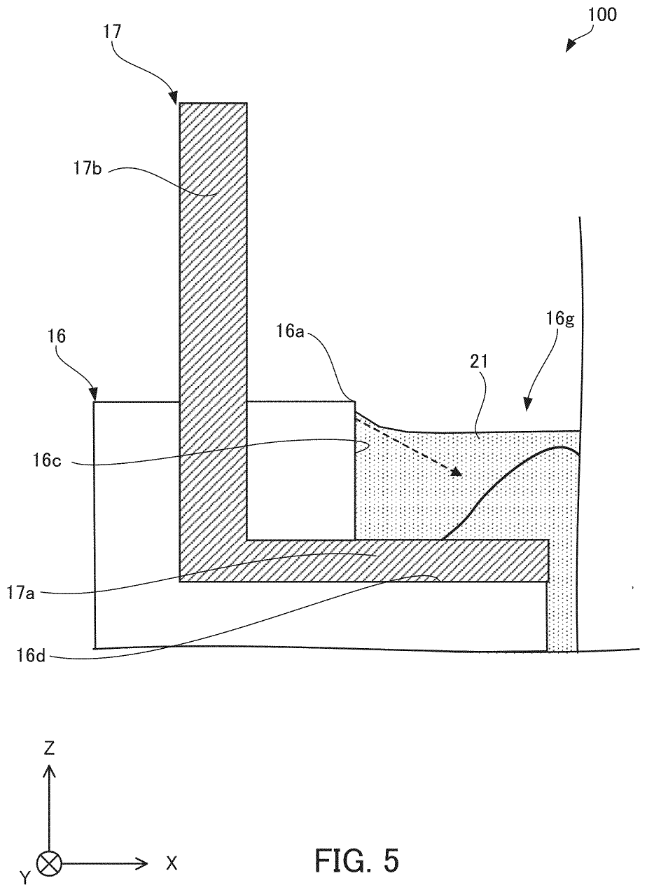

Here, a semiconductor device of a reference example will be described with reference to FIG. 5. FIG. 5 is a side sectional view of the semiconductor device according to the reference example. In this connection, unlike the semiconductor device 10, the semiconductor device 100 of the reference example does not have the space 22. The semiconductor device 100 has the same components as the semiconductor device 10, except the space 22. FIG. 5 illustrates a frame portion 16 of the semiconductor device 100 of the reference example around a step 16d.

In the semiconductor device 100, a sealing member 21 fills a housing space 16g of the frame portion 16. At this time, the outer edge of the sealing member 21 warps up above the center of the sealing member 21. When this semiconductor device 100 operates, its temperature changes. Since the frame portion 16 and the sealing member 21 have different linear expansion coefficients, internal stress is generated due to the temperature changes in the semiconductor device 100. Then, the stress is concentrated in the sealing member 21 of the semiconductor device 100 and a crack may occur. In addition, stress is likely to be concentrated at the interface between the sealing member 21 and the frame portion 16 that are made of different materials with different linear expansion coefficients. Especially, the stress is likely to be concentrated in the warped portion at the outer edge of the sealing member 21. Therefore, a crack may occur along a broken arrow of FIG. 5 in the sealing member 21 and may extend. This reduces the power cycle resistance of the semiconductor device 100, and in turn reduces the reliability of the semiconductor device 100 against temperature changes.

By contrast, in the semiconductor device 10, the contact area 21a of the sealing member 21 filling the housing space 16g of the frame portion 16 is positioned closer to the semiconductor chips 13a and 13b than the sealing surface 21b of the sealing member 21. That is, in the semiconductor device 10, the sealing connecting surface 21c of the sealing member 21 and the attachment area 16c2 of the frame portion 16 have the space 22 therebetween. Therefore, the joining area between the upper inner wall 16c of the frame portion 16 and the contact area 21a of the sealing member 21 is reduced to thereby reduce the generation of internal stress. This reduces the risk of occurrence of a crack in the sealing member 21 and prevents the crack, if it occurs, from extending.

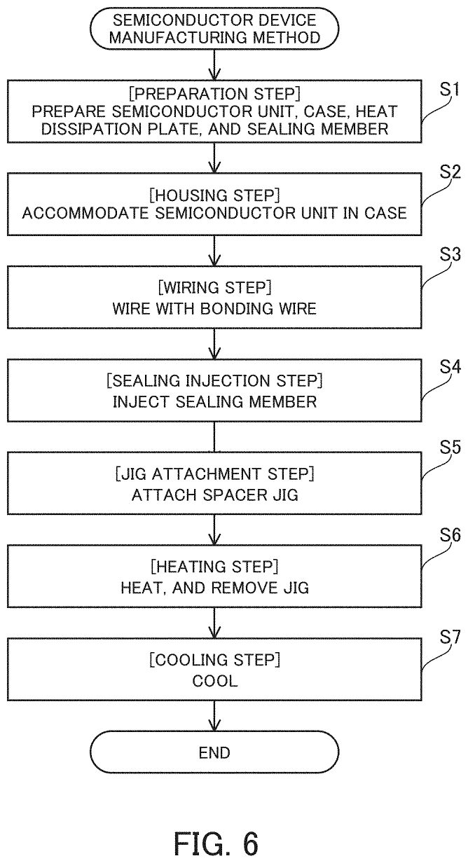

The following describes a method of manufacturing the semiconductor device 10 with reference to FIG. 6. FIG. 6 is a flowchart illustrating a semiconductor device manufacturing method according to the first embodiment. First, a preparation step is executed to prepare the semiconductor unit 11, case 15, and heat dissipation plate 14 (step S1 of FIG. 6). At this step, the components of the semiconductor device 10 are prepared. For example, the components include the semiconductor unit 11, case 15, heat dissipation plate 14, and sealing member 21. In this connection, in the semiconductor unit 11, the semiconductor chips 13a and 13b are bonded to the predetermined circuit patterns 12b of the insulated circuit substrate 12 in advance. In the case 15, the frame portion 16 and external connection terminals 17 are integrally formed in advance. In addition to the above components, other components and devices needed for manufacturing the semiconductor device 10 are prepared.

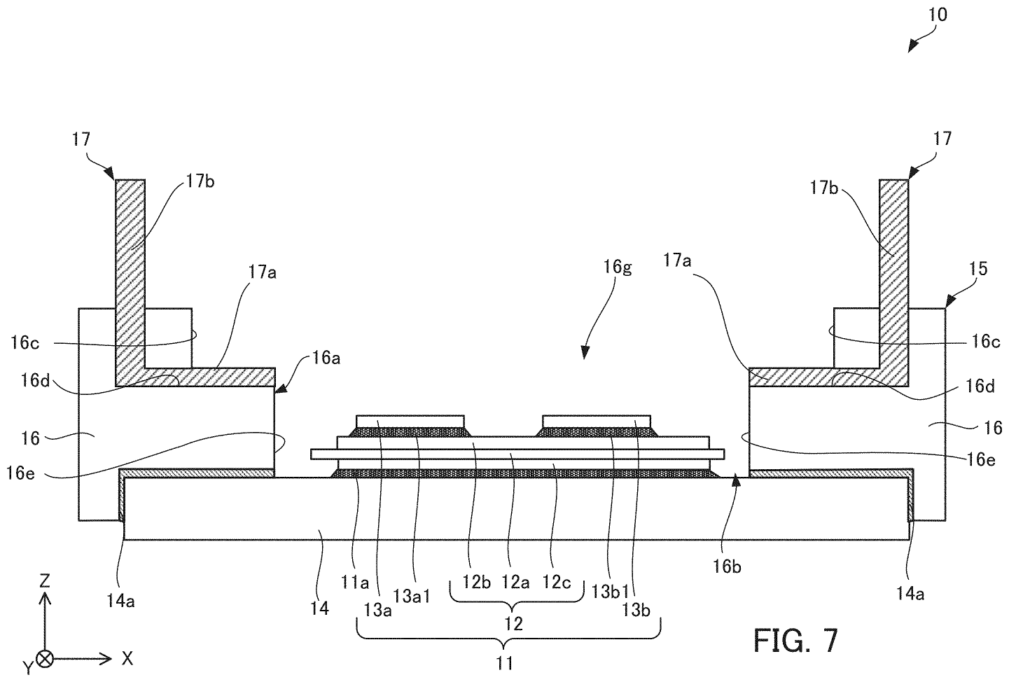

Then, a housing step is executed to accommodate the semiconductor unit 11 in the case 15 (step S2 of FIG. 6). This housing step will be described with reference to FIG. 7. FIG. 7 is a side sectional view for describing the housing step included in the semiconductor device manufacturing method according to the first embodiment. In this connection, FIG. 7 is a sectional view of a part corresponding to that illustrated in FIG. 1.

In this housing step, first, the semiconductor unit 11 is bonded to the front surface of the heat dissipation plate 14 via the bonding material 11a. In this case, the bonding material 11a may contain the same material as the bonding materials 13a1 and 13b1 as the main component. The case 15 is attached to the outer periphery of the heat dissipation plate 14 via the adhesive 14a. The adhesive 14a is cured by heating at a predetermined temperature for a predetermined period of time, so that the case 15 is bonded to the heat dissipation plate 14. By doing so, the semiconductor unit 11 is accommodated in the housing space 16g of the frame portion 16 as illustrated in FIG. 7.

Then, a wiring step of wiring with bonding wires is executed (step S3 of FIG. 6). This wiring step is a bonding step of connecting the inner wire portions 17a of the external connection terminals 17, and the semiconductor chips 13a and 13b and circuit patterns 12b of the insulated circuit substrate 12 with the bonding wires 20 where appropriate.

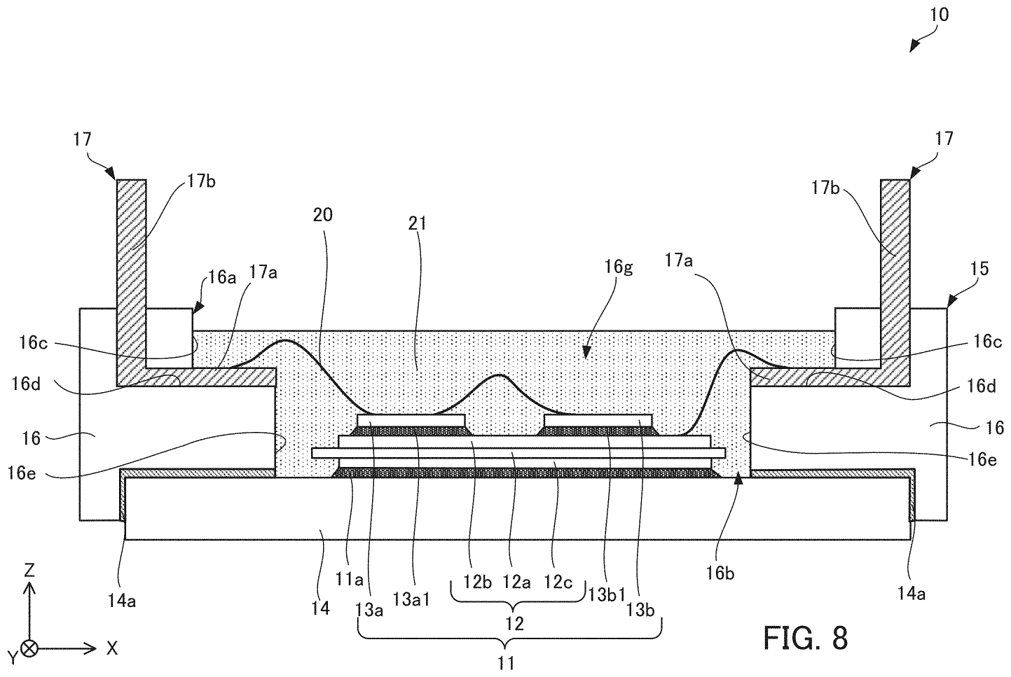

After that, a sealing injection step of filling the housing space 16g of the case 15 with the sealing member 21 is executed (step S4 of FIG. 6). This sealing injection step will be described with reference to FIG. 8. FIG. 8 is a side sectional view for describing the sealing injection step included in the semiconductor device manufacturing method according to the first embodiment. In this connection, FIG. 8 illustrates a situation after the wiring step and the sealing injection step are executed in FIG. 7. As illustrated in FIG. 8, the sealing member 21 is injected in the housing space 16g of the frame portion 16 until the sealing member 21 completely seals the bonding wires 20. In addition, at this time, the entire side surface of the sealing member 21 contacts the upper inner wall 16c. At this stage, the sealing member 21 is not yet heated.

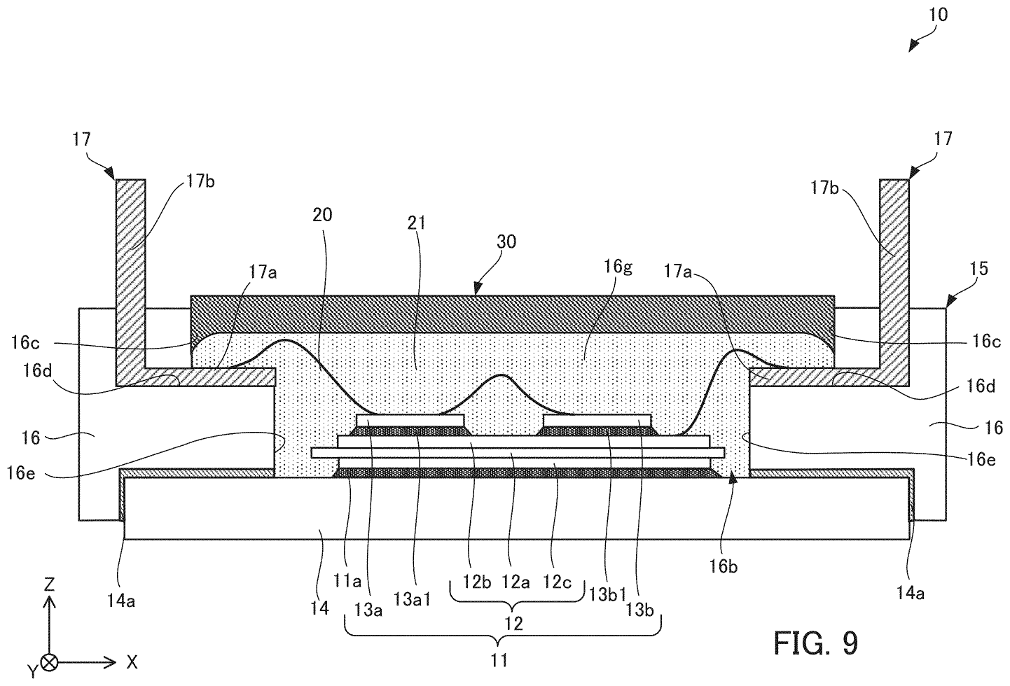

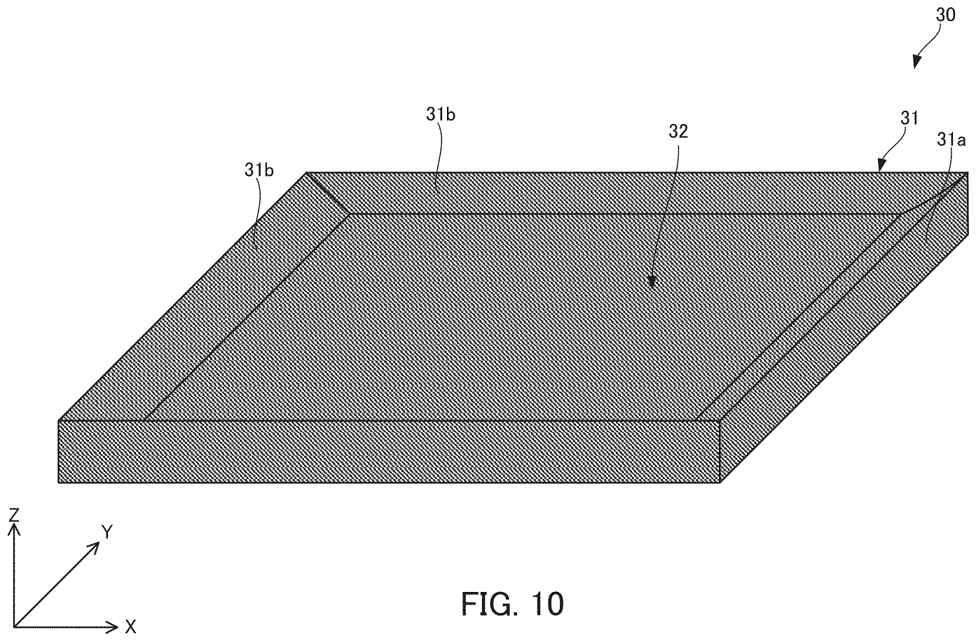

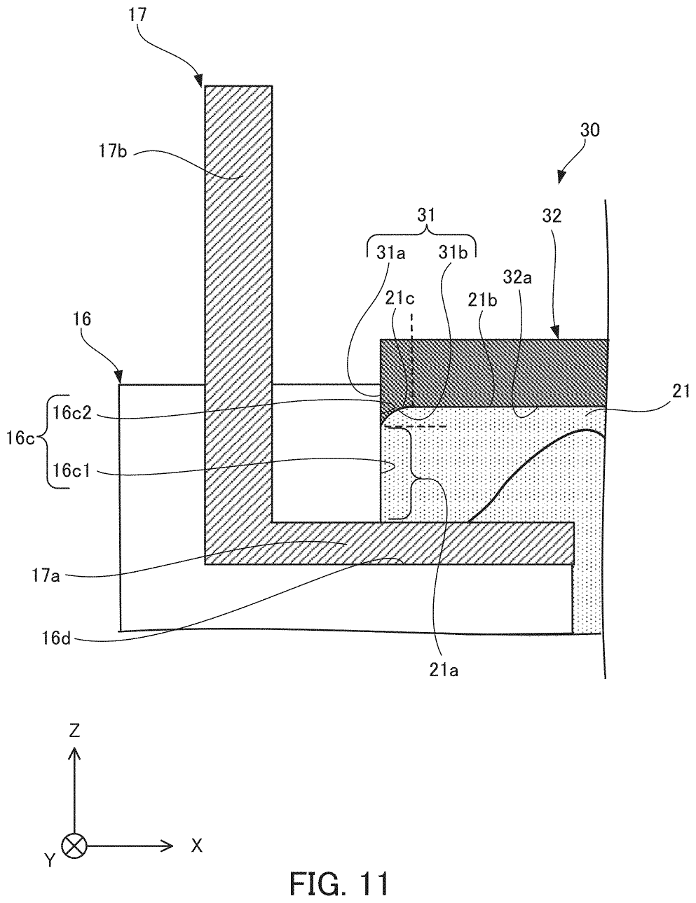

Then, a jig attachment step of attaching a spacer jig 30 to the top opening 16a is executed (step S5 of FIG. 6). This jig attachment step will be described with reference to FIGS. 9 to 11. FIG. 9 is a side sectional view for describing the jig attachment step included in the semiconductor device manufacturing method according to the first embodiment. FIG. 10 illustrates a jig that is used in the semiconductor device manufacturing method according to the first embodiment. FIG. 11 is a side sectional view of a main part for describing the jig attachment step included in the semiconductor device manufacturing method according to the first embodiment. In this connection, FIG. 9 illustrates a situation after the jig attachment step is executed in FIG. 8. In FIG. 10, the attachment side (inner side) of the spacer jig 30 faces upward. FIG. 11 illustrates part of the frame portion 16 of FIG. 9 around a step 16d.

The heating of the sealing member 21 starts at step S6 after the filling with the sealing member 21, and the spacer jig 30 is attached to the top opening 16a before the sealing member 21 starts to cure. As illustrated in FIG. 10, the spacer jig 30 has a spacer portion 31 and a lid portion 32. The spacer portion 31 has a frame shape. The lid portion 32 is rectangular in plan view and has the same size and the same shape as the top opening 16a. The spacer portion 31 is continuously provided in a loop shape along the entire periphery of the outer edge of the lid portion 32.

In the sectional view of the spacer jig 30 attached to the top opening 16a, the spacer portion 31 has such a tapered shape that the spacer portion 31 becomes thicker as it goes from the lower end thereof toward the top opening 16a. This spacer portion 31 has an outer surface 31a and an adhesion principal surface 31b. The outer surface 31a is continuously provided in a loop shape along the entire outer periphery of the spacer portion 31. When the spacer jig 30 is attached to the top opening 16a, the spacer portion 31 contacts the attachment area 16c2 of the upper inner wall 16c as illustrated in FIG. 11. Note that the outer surface 31a contacts the attachment area 16c2 of the inner wall 16h on each long side of the frame portion 16. Therefore, the outer surface 31a extends in a substantially vertical direction, and is partly substantially parallel to the Y-Z plane and is partly substantially parallel to the X-Z plane.

The adhesion principal surface 31b connects to the outer surface 31a along the entire periphery of the outer surface 31a and has an acute angle with respect to the outer surface 31a in the sectional view of the spacer jig 30 attached to the top opening 16a. The adhesion principal surface 31b adheres to the outer edge (peripheral edge) of the sealing member 21. The adhesion principal surface 31b rises from the outer surface 31a with an acute angle with respect to the attachment area 16c2 of the upper inner wall 16c and then has an R-shaped surface. The lid portion 32 has a lid surface 32a. The lid surface 32a is substantially parallel to the X-Y plane when the spacer jig 30 is attached to the top opening 16a. Therefore, the lid surface 32a contacts the front surface of the sealing member 21 when the spacer jig 30 is attached to the top opening 16a. In addition, the lid surface 32a connects to the adhesion principal surface 31b connecting to the outer surface 31a. Therefore, the spacer jig 30 is recessed on its inner side (the side attached to the sealing member 21).

This spacer jig 30 is attached to the top opening 16a of the frame portion 16 such that the spacer jig 30 is placed on the sealing member 21 that has not started to cure yet, as illustrated in FIGS. 9 and 11. The spacer portion 31 enters the outer edge of the sealing member 21 in the housing space 16g. The outer surface 31a of the spacer portion 31 contacts the attachment area 16c2 of the upper inner wall 16c. The adhesion principal surface 31b convers the peripheral edge of the sealing member 21, and the lid surface 32a of the lid portion 32 covers the front surface of the sealing member 21.

Then, a heating step of heating the sealing member 21 is executed (step S6 of FIG. 6). The sealing member 21 is heated while the spacer jig 30 is attached. When a predetermined curing temperature (primary temperature) is reached thereafter, this temperature is kept for a predetermined period of time to cure the sealing member 21 (primary curing). When the predetermined period of time has passed, the temperature is further increased. When the temperature is increased to a predetermined curing temperature (secondary temperature) thereafter, the temperature is kept for a predetermined period of time to cure the sealing member 21 (secondary curing). In this embodiment, the primary and secondary curing is performed to cure the sealing member 21. Tertiary and subsequent curing may be performed according to necessity.

The spacer jig 30 may be removed after the sealing member 21 is cured to some extent. In this case, the spacer jig 30 may be removed any time after the primary curing is performed. The shape of the spacer jig 30 has been transferred to the sealing member 21 obtained after the removal of the spacer jig 30. The space 22 is formed between the sealing connecting surface 21c of the sealing member 21 and the attachment area 16c2 of the upper inner wall 16c of the frame portion 16.

Then, the heating is stopped, and a cooling step is executed (step S7 of FIG. 6). After heating is performed at step S6 and the spacer jig 30 is removed, the heating of the sealing member 21 is stopped to cool the heated sealing member 21. In the manner described above, the semiconductor device 10 illustrated in FIGS. 1 to 4 is obtained.

The semiconductor device 10 manufactured as described above includes the semiconductor chips 13a and 13b, case 15, and sealing member 21. The case 15 has the upper inner wall 16c communicating with the top opening 16a, and the upper inner wall 16c surrounds the housing space 16g for accommodating the semiconductor chips 13a and 13b along the top opening 16a. The sealing member 21 injected in the housing space 16g has the contact area 21a contacting the upper inner wall 16c on the side surface thereof and seals the semiconductor chips 13a and 13b. The contact area 21a of the sealing member 21 is positioned closer to the semiconductor chips 13a and 13b than the sealing surface 21b of the sealing member 21. That is, the space 22 is formed between the sealing connecting surface 21c of the sealing member 21 at the outer edge (peripheral edge) thereof and the attachment area 16c2 of the upper inner wall 16c of the frame portion 16. Therefore, the joining area between the upper inner wall 16c of the frame portion 16 and the contact area 21a of the sealing member 21 is reduced to thereby reduce the generation of internal stress. This results in reducing the risk of occurrence of a crack in the sealing member 21 and also preventing the crack, if it occurs, from extending. Thus, it is possible to prevent a reduction in the reliability of the semiconductor device 10 against temperature changes.

### Modification 1-1

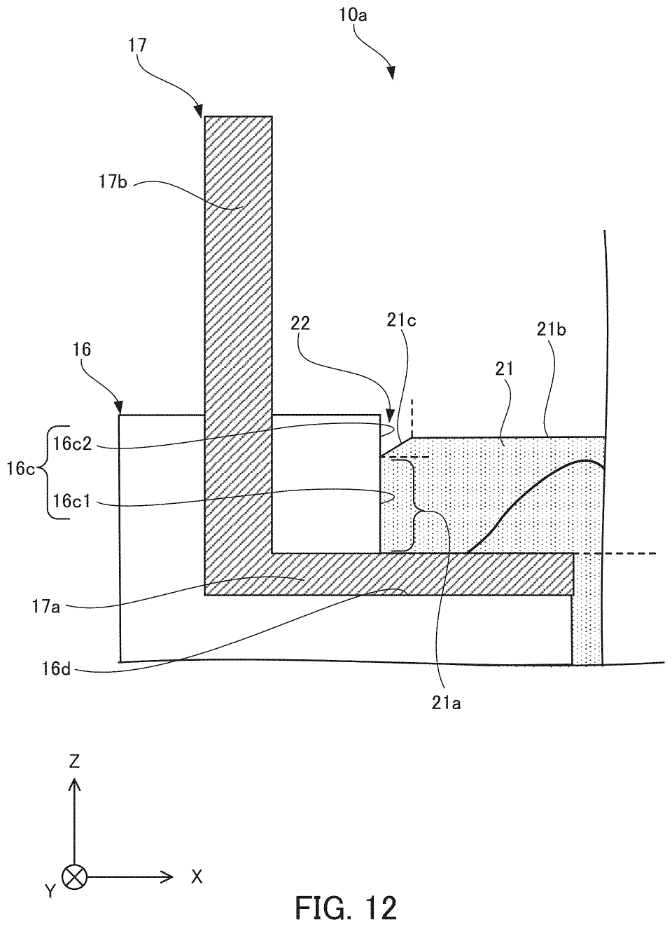

A semiconductor device 10a according to a modification 1-1 of the first embodiment will be described with reference to FIG. 12. FIG. 12 is a sectional view of a main part of a semiconductor device according to the modification 1-1 of the first embodiment. In this connection, FIG. 12 is a sectional view of a part of a semiconductor device 10a corresponding to the part illustrated in FIG. 4.

The semiconductor device 10a has the same configuration as the semiconductor device 10 of FIGS. 1 to 4 except that a sealing connecting surface 21c of the semiconductor device 10a is inclined. As with the semiconductor device 10, in the semiconductor device 10a, a sealing member 21 is injected in a housing space 16g of a frame portion 16 to seal a semiconductor unit 11. The sealing member 21 has a contact area 21a, a sealing surface 21b, and a sealing connecting surface 21c. The contact area 21a and sealing surface 21b are identical to those of the semiconductor device 10 of FIGS. 1 to 4.

The sealing connecting surface 21c connects the outer edge of the sealing surface 21b and the outer edge at the upper end of the contact area 21a at the side thereof where a top opening 16a is positioned, over the entire periphery. In addition, in side view, the sealing connecting surface 21c rises from the contact area 21a such that the sealing connecting surface 21c forms an acute angle with respect to an attachment area 16c2 of an upper inner wall 16c. The sealing connecting surface 21c extends with the rising angle kept and connects to the outer edge of the sealing surface 21b. In this manner, the sealing connecting surface 21c connects the contact area 21a and the sealing surface 21b over the entire periphery. In addition, the semiconductor device 10a has a space 22 between the sealing connecting surface 21c of the sealing member 21 and the attachment area 16c2 of the frame portion 16. Therefore, the joining area between the upper inner wall 16c of the frame portion 16 and the contact area 21a of the sealing member 21 is reduced to thereby reduce the generation of internal stress. This results in reducing a risk of occurrence of a crack in the sealing member 21 and also preventing the crack, if it occurs, from extending.

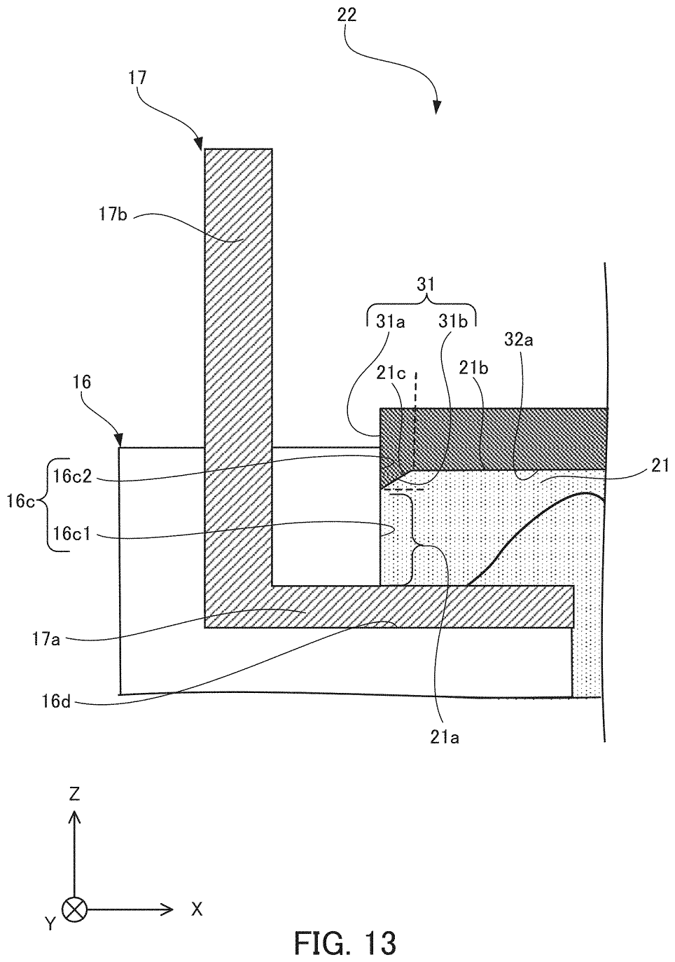

A method of manufacturing this semiconductor device 10a will be described with reference to FIGS. 6 and 13. FIG. 13 is a sectional view of the main part for describing a jig attachment step included in a semiconductor device manufacturing method according to the modification 1-1 of the first embodiment. The semiconductor device 10a may be manufactured in accordance with the flowchart of FIG. 6. At step S5 of the flowchart of FIG. 6, a spacer jig 30 illustrated in FIG. 13 is used. In the sectional view of the spacer jig 30 attached to the top opening 16a, a spacer portion 31 of the spacer jig 30 has such a tapered shape that the spacer portion 31 becomes thicker as it goes from the lower end thereof toward the top opening 16a. In addition, the spacer portion 31 has an outer surface 31a and an adhesion principal surface 31b. The outer surface 31a is formed in the same manner as that used for the semiconductor device 10.

The adhesion principal surface 31b connects to the outer surface 31a along the entire periphery of the outer surface 31a, extends at an acute angle with respect to the outer surface 31a in the sectional view of the spacer jig 30 attached to the top opening 16a, and connects to the lid surface 32a of a lid portion 32 of the spacer portion 31. That is to say, the adhesion principal surface 31b is inclined.

This spacer jig 30 is attached to the top opening 16a of the frame portion 16 such that the spacer jig 30 is placed on the sealing member 21 that has not started to cure yet, as illustrated in FIG. 13. The spacer portion 31 enters the outer edge of the sealing member 21 in the housing space 16g. The outer surface 31a of the spacer portion 31 contacts the attachment area 16c2 of the upper inner wall 16c. The adhesion principal surface 31b covers the peripheral edge of the sealing member 21, and the lid surface 32a of the lid portion 32 covers the front surface of the sealing member 21. After that, steps S6 and S7 are executed to thereby obtain the semiconductor device 10a illustrated in FIG. 12.

In the semiconductor device 10a configured as above, the space 22 is formed between the sealing connecting surface 21c at the peripheral edge of the sealing member 21 and the attachment area 16c2 of the upper inner wall 16c of the frame portion 16. Therefore, the joining area between the upper inner wall 16c of the frame portion 16 and the contact area 21a of the sealing member 21 is reduced to thereby reduce the generation of internal stress. This results in reducing the risk of occurrence of a crack in the sealing member 21 and also preventing the crack, if it occurs, from extending. Thus, it is possible to prevent a reduction in the reliability of the semiconductor device 10 against temperature changes.

### Second Embodiment

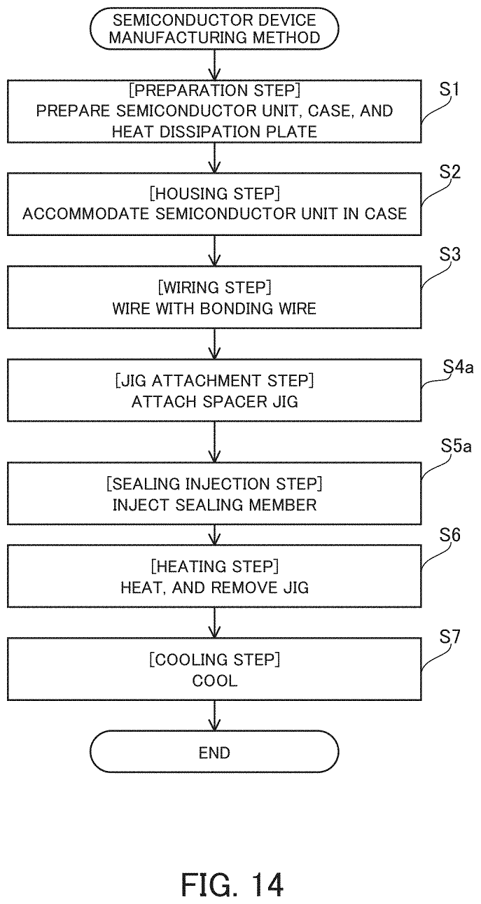

In a second embodiment, a hole is formed to penetrate through the lid portion 32 of the spacer jig 30 of the first embodiment. A method of manufacturing the semiconductor device 10 using this spacer jig will be described with reference to FIG. 14. FIG. 14 is a flowchart illustrating a semiconductor device manufacturing method according to the second embodiment. In this connection, the same step numbers as used in FIG. 6 are given to the corresponding steps of FIG. 14.

To manufacture the semiconductor device 10, first, a preparation step (step S1 of FIG. 14), a housing step (step S2 of FIG. 14), and a wiring step (step S3 of FIG. 14) are executed in order, as in the flowchart of FIG. 6.

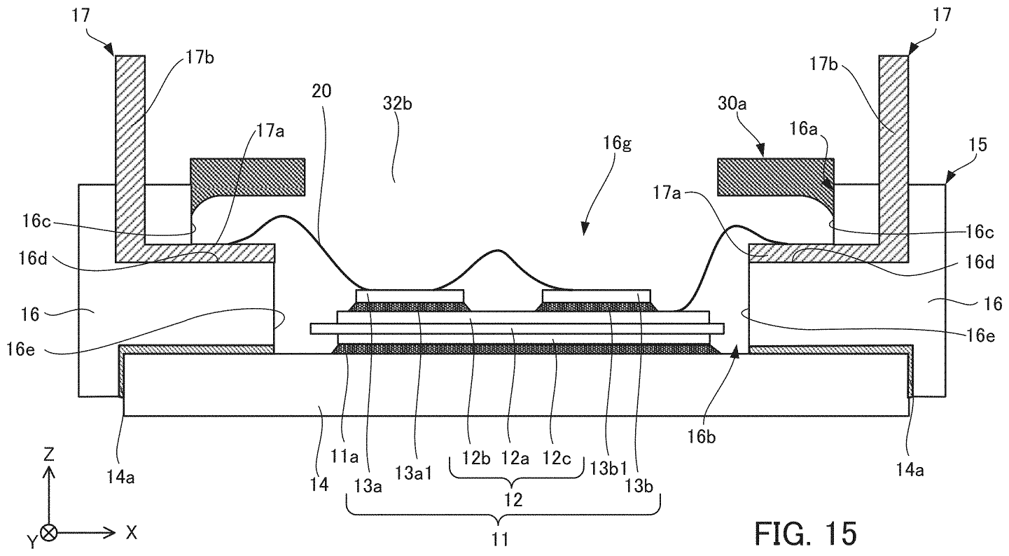

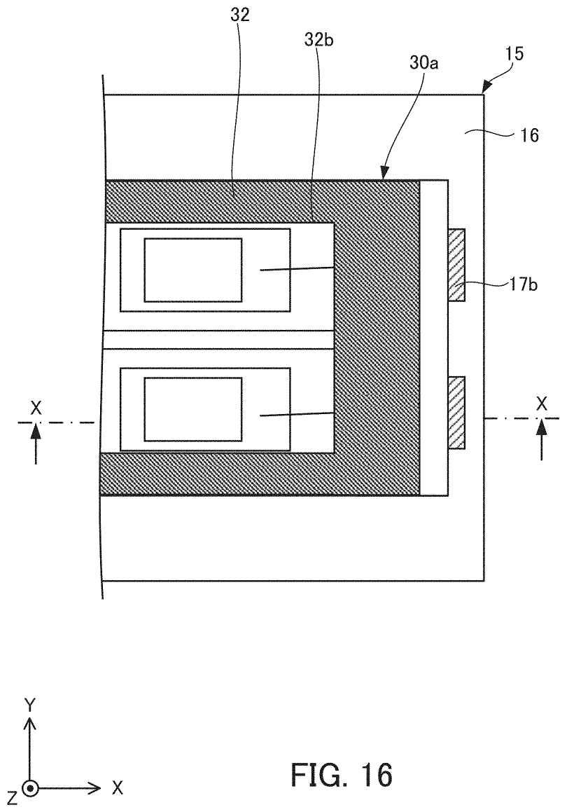

After that, in the second embodiment, a jig attachment step of attaching a spacer jig 30a to the top opening 16a is executed (step S4a of FIG. 14). The jig attachment step will be described with reference to FIGS. 15 and 16. FIG. 15 is a side sectional view for describing the jig attachment step included in the semiconductor device manufacturing method according to the second embodiment. FIG. 16 is a plan view of a main part for describing the jig attachment step included in the semiconductor device manufacturing method according to the second embodiment. FIG. 16 is a plan view around an external connection terminal 17 illustrated in FIG.

15.

The spacer jig 30a for use in the jig attachment step of step S4a of FIG. 14 has an opening hole 32b in the lid portion 32. The opening hole 32b penetrates through the lid portion 32. For example, the size of the opening hole 32b corresponds to that of the insulated circuit substrate 12 in plan view. In this connection, not only one but also a plurality of opening holes 32b may be formed.

When this spacer jig 30a is attached to the frame portion 16, the outer surface 31a of the spacer portion 31 contacts the attachment area 16c2 of the upper inner wall 16c, and the spacer jig 30a is held at the top opening 16a as illustrated in FIGS. 15 and 16.

After that, a sealing injection step of filling the housing space 16g with the sealing member 21 is executed (step S5a of FIG. 14). The sealing member 21 is injected in the housing space 16g from the opening hole 32b of the spacer jig 30a attached to the top opening 16a at step S4a. The sealing surface 21b of the injected sealing member 21 is positioned between opposite sides of the adhesion principal surface 31b of the spacer jig 30a. The adhesion principal surface 31b of the spacer jig 30a prevents the outer edge of thus injected sealing member 21 from contacting the attachment area 16c2 of the upper inner wall 16c. This prevents the generation of corners at the outer edge of the sealing member 21. After that, steps S6 and S7 are executed as in the first embodiment. Note that, in the heating step of step S6, gas volatized from the sealing member 21 is exhausted from the opening hole 32b of the spacer jig 30a. Since no gas is accumulated in the spacer jig 30a, the misalignment of the spacer jig 30a due to the gas is prevented. Therefore, the space 22 may be formed between the sealing connecting surface 21c at the peripheral edge of the sealing member 21 and the attachment area 16c2 of the upper inner wall 16c of the frame portion 16. In the manner described above, the semiconductor device 10 is obtained.

The semiconductor device configured as above makes it possible to reduce concentration of internal stress due to temperature changes, to prevent the occurrence and extension of a crack, and thus to prevent its reliability against temperature changes.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip;
a case having
an opening formed therein, and
an inner wall communicating with the opening, the inner wall surrounding a housing space for accommodating the semiconductor chip; and
a sealing member filling the housing space to seal the semiconductor chip, the sealing member having a side surface and a sealing surface, the side surface having a contact area contacting the inner wall of the case,
wherein the contact area is positioned, in a depth direction of the semiconductor device, closer to the semiconductor chip than is the sealing surface of the sealing member.

2. The semiconductor device according to claim 1, wherein
the inner wall includes a contacted area and an attachment area, respectively in contact with, and not in contact with, the contact area of the sealing member,
the sealing member further has a sealing connecting surface connecting an outer edge of the sealing surface and an upper edge of the contact area over an entire periphery of the sealing member, and
the sealing connecting surface and the attachment area of the inner wall join each other in an acute angle in a side view of the semiconductor device.

3. The semiconductor device according to claim 2, wherein the sealing connecting surface has a chamfered shape over the entire periphery of the sealing member.

4. The semiconductor device according to claim 2, wherein at least a part of the contacted area of the inner wall is rougher than the attachment area.

5. The semiconductor device according to claim 1, wherein the case contains a polyphenylene sulfide (PPS) resin as a main component thereof.

6. The semiconductor device according to claim 1, wherein the sealing member contains a thermosetting resin as a main component thereof.

7. The semiconductor device according to claim 6, wherein the thermosetting resin contains an epoxy resin as a main component thereof.

8. A semiconductor device manufacturing method, comprising:
preparing a semiconductor chip, a case, and a sealing member, the case having an opening formed therein, and an inner wall communicating with the opening and surrounding a housing space, the inner wall having a contacted area and an attachment area, the attachment area being positioned closer to the opening than the contacted area;
disposing the semiconductor chip in the housing space of the case;
injecting the sealing member in the housing space, such that the sealing member has, on a side surface thereof, a contact area that contacts the contacted area of the inner wall, to thereby seal the semiconductor chip; and
attaching, before or after the injecting of the sealing member, a spacer jig including a spacer portion, such that the spacer portion contacts the attachment area of the inner wall over an entire periphery of the opening.

9. The semiconductor device manufacturing method according to claim 8, wherein the spacer portion has a tapered shape, such that a thickness of the spacer portion, in a direction perpendicular to the inner wall, increases as the spacer portion is closer to the opening in a sectional view of the spacer jig attached to the opening.

10. The semiconductor device manufacturing method according to claim 9, wherein the spacer portion has
an outer surface, a portion of which contacts the attachment area over an entire periphery of the inner wall, and
an adhesion principal surface that connects to the outer surface over an entire periphery of the outer surface, joins the outer surface in an acute angle in the sectional view, and adheres to the sealing member.

11. The semiconductor device manufacturing method according to claim 10, wherein the adhesion principal surface is a curved surface.

12. The semiconductor device manufacturing method according to claim 10, wherein the adhesion principal surface is inclined at the acute angle with respect to the attachment area of the inner wall.

13. The semiconductor device manufacturing method according to claim 8, wherein
the spacer jig further includes a lid portion, and
the spacer portion is formed along an outer periphery of the lid portion.

14. The semiconductor device manufacturing method according to claim 13, wherein the lid portion has one or more holes formed therein.

15. The semiconductor device manufacturing method according to claim 14, wherein
the spacer jig is attached before the injecting of the sealing member, and
the injecting of the sealing member includes injecting the sealing member from the one or more holes of the lid portion.
